(19) United States
(12) Patent Application Publication
(10) Pub. No.: US 2025/0003056 A1
(43) Pub. Date: Jan. 2, 2025

(54) AMORPHOUS TRANSPARENT CONDUCTIVE OXIDE FILMS AND METHODS OF FABRICATING THE SAME

(71) Applicant: CORNING INCORPORATED, Corning, NY (US)

(72) Inventors: Paulo Clovis Dainese, Jr., Painted Post, NY (US); Wei Jiang, Vestal, NY (US); Robert George Manley, Ocala, FL (US); Bin Zhu, Ithaca, NY (US)

(21) Appl. No.: 18/710,273

(22) PCT Filed: Nov. 8, 2022
(86) PCT No.: PCT/US2022/049198

§ 371 Date: May 15, 2024

Related U.S. Application Data
(60) Provisional application No. 63/281,864, filed on Nov. 22, 2021.

(51) Int. Cl. C23C 14/34; C23C 14/08; C23C 14/58

(52) U.S. Cl. CPC C23C 14/3414; C23C 14/08; C23C 14/5806

(57) ABSTRACT

A composite includes a substrate and a target material, wherein the target material includes indium oxide (In₂O₃), tin oxide (SnO₂), and gallium oxide (Ga₂O₃), and a method for making the same. The method includes positioning the substrate and a target in a chamber and applying radio frequency (RF) power to the chamber to sputter ions of target material from the target onto the substrate.

### CROSS-REFERENCE TO RELATED APPLICATIONS

This application claims the benefit of priority under 35 U.S.C. § 119 of U.S. Provisional Serial Application No.: 63/281,864, filed on Nov. 22, 2021, the content of which is relied upon and incorporated herein by reference in its entirety.

### FIELD

The present disclosure relates generally to amorphous transparent conductive oxide films and methods of fabricating the same.

### BACKGROUND

Amorphous transparent conductive oxide (TCO) films have been used for many optoelectronic and photovoltaic applications, such as displays, light emitting diodes, and solar cells. For instance, silicon photonics has emerged as an optical technology for data communications, with applications ranging from long-haul transmissions, short-reach communications in datacenters and supercomputers, to intra-chip interconnects. In the case of datacenter interconnects, with rapid growth of datacom traffic demand electro-optic (EO) modulators, there is increased demand for high modulation speed over a large optical bandwidth with a small device footprint and low power consumption and, in this regard, substantial efforts have been made to improve the performance of the integrated silicon EO modulators. However, due to weak light-matter interaction in silicon, conventional broadbandMach-Zenhder modulators usually suffer from low efficiency, high insertion loss, and large footprint. By utilizing a micro-resonator structure, the footprint can be significantly reduced, but such devices exhibit narrow optical bandwidth and strong thermal instability. Consequently, additional thermal stabilization elements are needed, which increase total power consumption substantially. More efficient electro-absorption (EA) modulators have recently been demonstrated based on tensile-strained Ge quantum wells or bulk Ge/Si materials. However, such are fundamentally narrow-band modulators, where the desired operating wavelength is determined by material composition, and temperature variation can exert a significant bandgap and operation wavelength drift. Thus, they require sophisticated epitaxial growth and thermal control, which increases process complexity and cost.

### SUMMARY

Embodiments disclosed herein include a method of manufacturing a composite of a target material and a substrate. The method includes positioning the substrate and a target in a chamber and applying radio frequency (RF) power to the chamber to sputter ions of target material from the target onto the substrate. The target material includes indium oxide (In₂O₃), tin oxide (SnO₂), and gallium oxide (Ga₂O₃).

Embodiments disclosed herein also include a composite that includes a substrate and a target material. The target material includes indium oxide (In₂O₃), tin oxide (SnO₂), and gallium oxide (Ga₂O₃).

Additional features and advantages of the embodiments disclosed herein will be set forth in the detailed description which follows, and in part will be readily apparent to those skilled in the art from that description or recognized by practicing the disclosed embodiments as described herein, including the detailed description which follows, the claims, as well as the appended drawings.

It is to be understood that both the foregoing general description and the following detailed description present embodiments intended to provide an overview or framework for understanding the nature and character of the claimed embodiments. The accompanying drawings are included to provide further understanding, and are incorporated into and constitute a part of this specification. The drawings illustrate various embodiments of the disclosure, and together with the description explain the principles and operations thereof.

### BRIEF DESCRIPTION OF THE DRAWINGS

FIG. 1 is a side schematic perspective view of an example RF sputtering apparatus and process in accordance with embodiments disclosed herein;

FIG. 2 is a side view of a substrate and layer of target material in accordance with embodiments disclosed herein;

FIG. 3 is a side schematic perspective view of an example thermal annealing apparatus and process in accordance with embodiments disclosed herein;

FIG. 4 is a chart showing real and imaginary parts of the complex refractive index as a function of wavelength extracted from spectroscopic ellipsometry using the Drude-Lorentz model in accordance with embodiments disclosed herein;

FIG. 5 is a chart showing extracted carrier density in as-deposited films for different oxygen fractions in accordance with embodiments disclosed herein;

FIG. 6 is a chart showing real and imaginary parts of the complex refractive index as a function of wavelength extracted from spectroscopic ellipsometry using the Drude-Lorentz model in accordance with embodiments disclosed herein; and

FIG. 7 is a chart showing epsilon as a function of wavelength for a series of annealed films in accordance with embodiments disclosed herein.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, for example by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, the term “transparent” refers to a material that transmits at least about 50% of light in a wavelength range of from about 400 nanometers to about 750 nanometers.

As used herein, the term “conductive” refers to a material having an electrical conductivity at 25° C. of at least about 100 Ω⁻¹·cm⁻¹.

Amorphous transparent conductive oxide (TCO) films have been used for many optoelectronic and photovoltaic applications, such as displays, light emitting diodes, and solar cells. Embodiments disclosed herein include methods for depositing such films on a substrate. In particular, embodiments disclosed herein include methods for depositing indium gallium tin oxide (IGTO) onto a substrate carrier using radio frequency (RF) sputtering, which may be followed by thermal annealing.

RF sputtering is a technique known to persons having ordinary skill in the art that can be utilized to deposit thin films onto a substrate. RF Sputtering involves passing an energetic wave through generally inert gas in a low pressure (e.g., vacuum) chamber causing ionization of the gas. A target material which is to become the thin film, is bombarded by these ions, which results in sputtering off atoms of the target material as a fine spray, ultimately covering the substrate.

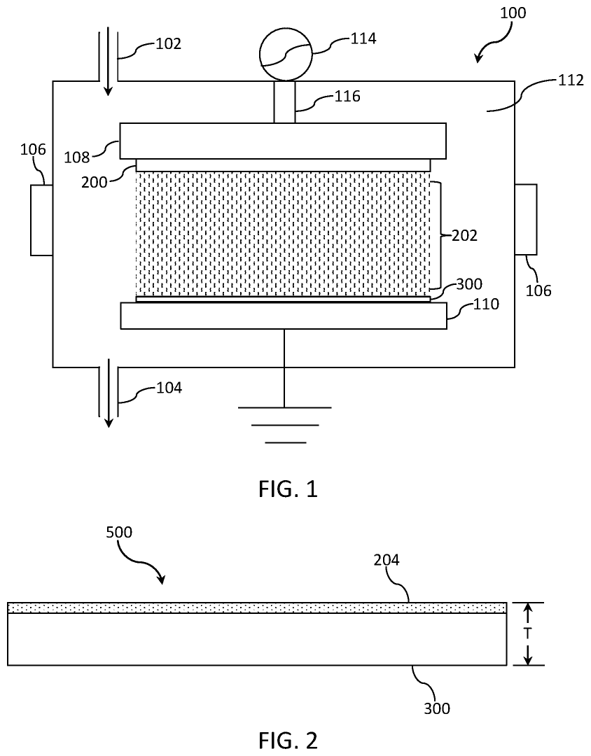

FIG. 1 shows a side schematic perspective view of an example RF sputtering apparatus 100 and process in accordance with embodiments disclosed herein. RF sputtering apparatus 100 includes chamber 112, gas inlet 102, and vacuum pump 104. Gas inlet 102 is configured to flow a gaseous fluid into chamber 112. Vacuum pump 104 is configured to evacuate gaseous fluid out of chamber 112. RF sputtering apparatus 100 also includes power source (e.g., RF power source) 114, target holder 108, which is configured to hold target 200, substrate holder 110, which is configured to hold substrate 300, and electrical connection 116 between power source 114 and target holder 108. In certain exemplary embodiments, target holder 108 acts as a cathode and substrate holder 110 acts as an anode. RF sputtering apparatus also includes heating elements 106.

In certain exemplary embodiments, gaseous fluid comprises an inert gas, such as at least one of helium, nitrogen, neon, or argon. Gaseous fluid may also comprise at least one other (i.e., non-inert) gas, such as at least one of oxygen or hydrogen. In certain exemplary embodiments, gaseous fluid comprises a combination of at least one inert gas and at least one non-inert gas. In such combinations, the fraction of inert gas may, for example, be at least about 90 mol %, such as at least about 95 mol %, and may range from about 90 mol % to about 99.9 mol %, such as from about 95 mol % to about 99 mol %. In certain exemplary embodiments, gaseous fluid comprises argon, including a combination of argon and oxygen, wherein the fraction of argon ranges from about 90% mol % to about 99.9% mol %, such as from about 95 mol % to about 99 mol % and the fraction of oxygen ranges from about 0.1 mol % to about 10 mol %, such as from about 1 mol % to about 5 mol %.

In certain exemplary embodiments, vacuum pump 104 is configured to evacuate gaseous fluid out of chamber 112 such that the absolute pressure inside chamber 112 is less than about 25 mTorr, such as less than about m10 Torr, including from about 0.5 mTorr to about 25 mTorr and further including from about 1 mTorr to about 10 mTorr and still further including from about 2 mTorr to about 5 mTorr.

In certain exemplary embodiments, power source 114 can impart an RF power ranging from about 100 Watts (W) to about 10 kilowatts (kW), such as from about 500 Watts to about 1 kilowatt (kW). In addition, chamber 112 can, for example (e.g., through operation of heating elements 106), be maintained at a temperature of at least about 20° C., such as a temperature ranging from about 20° C. to about 600° C., such as from about 60° C. to about 500° C., and further such as from about 100° C. to about 400° C.

Operation of power source 114 results in bombardment of target 200 with ions of gaseous fluid such that atoms 202 of target 200 are sputtered away from target 200 and onto substrate 300 in order to deposit a layer (or thin film) of target material on at least a surface of substrate 300. While not limited, the deposition rate of target material onto substrate 300 (i.e., rate of increase of thickness of target material on substrate 300) may, for example, range from about 0.1 nanometers to about 10 nanometers per minute, such as from about 0.5 nanometers to about 5 nanometers per minute.

FIG. 2 shows a side view of a composite 500 of a substrate 300 and layer (or thin film) 204 of target material in accordance with embodiments disclosed herein. In certain exemplary embodiments, a thickness (i.e., dimension in direction “T” of FIG. 2) of substrate 300 may range from about 100 microns (μm) to about 10 millimeters (mm), such as from about 500 microns (μm) to about 5 millimeters, and a thickness of layer (or thin film) 204 may range from about 1 nanometer (nm) to about 10 microns (μm), such as from about 10 nanometers (nm) to about 1 micron (μm), and further such as from about 50 nanometers (nm) to about 200 nanometers (nm).

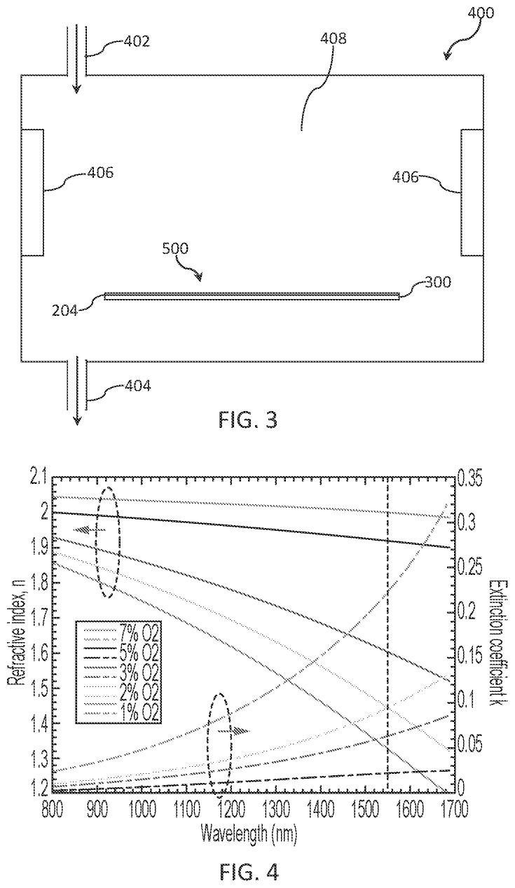

Subsequent to deposition of layer (or thin film) 204 of target material onto substrate 300, composite 500 of substrate 300 and layer (or thin film) 204 may be thermally annealed. FIG. 3 shows a side schematic perspective view of an example thermal annealing apparatus 400 and process in accordance with embodiments disclosed herein. Thermal annealing apparatus 400 includes chamber 408, gas inlet 402, and gas outlet 404. Gas inlet 402 is configured to flow a gaseous fluid into chamber 408. Gas outlet 404 is configured to evacuate gaseous fluid out of chamber 408. Thermal annealing apparatus 400 also includes heating elements 406.

In certain exemplary embodiments, gaseous fluid comprises an inert gas, such as at least one of helium, nitrogen, neon, or argon. Gaseous fluid may also comprise at least one other (i.e., non-inert) gas, such as at least one of oxygen or hydrogen. In certain exemplary embodiments, gaseous fluid comprises a combination of at least one inert gas and at least one non-inert gas. In such combinations, the fraction of inert gas may, for example, be at least about 90 mol % such as at least about 95 mol %, and range from about 90 mol % to about 99.9 mol %, such as from about 95 mol % to about 99 mol %. In certain exemplary embodiments, gaseous fluid comprises nitrogen, including a combination of nitrogen and hydrogen, wherein the fraction of nitrogen ranges from about 90 mol % to about 99.9 mol %, such as from about 95 mol % to about 99 mol % and the fraction of hydrogen ranges from about 0.1 mol % to about 10 mol %, such as from about 1 mol % to about 5 mol %. Gaseous fluid may also comprise air.

In certain exemplary embodiments, chamber 408 may be maintained at a temperature (e.g., through operation of heating elements 406) of at least about 300° C., such as a temperature of from about 300° C. to about 500° C. In certain exemplary embodiments, chamber 408 may be maintained at a pressure ranging from about 1 mTorr to about 760 Torr (1 atm), such as from about 10 mTorr to about 100 Torr, and further such as from about 100 mTorr to about 10 Torr. In certain exemplary embodiments, thermal annealing may comprise maintaining the composite 500 in chamber 408 for a time of at least about 10 minutes, such as a time ranging from about 10 minutes to about 150 minutes, such as from about 20 minutes to about 100 minutes, and further such as from about 30 minutes to about 60 minutes.

Embodiments disclosed herein include those in which layer (or thin film) 204 of target material comprises indium oxide (In₂O₃), tin oxide (SnO₂), and gallium oxide (Ga₂O₃), including an amorphous transparent conductive composition comprising indium gallium tin oxide (IGTO). Specifically, IGTO can be formed in the ternary system Ga₂O₃·In₂O₃·SnO₂, wherein the Ga:In:Sn ratio may vary.

The complex dielectric permittivity of IGTO can be described by the Drude-Lorentz model:

$$ε = {ε}^{′} + i {ε}^{″} = {ε}_{∞} - \frac{{ω}_{p}^{2}}{ω ( ω + i {γ}_{D} )} + \frac{{f}_{L} {ω}_{L}^{2}}{{ω}_{L}^{2} - {ω}^{2} - i {γ}_{L} ω}$$

where ε_{∞} is the background permittivity at high frequency, ω is the angular frequency, ωₚ is the plasma frequency given by

$${ω}_{p} = e \sqrt{\frac{N}{{ε}_{0} {m}^{*}}} ,$$

where e is elementary charge, N is the free electron (or carrier) density, m* is the effective mass of the electrons in the conduction band, ε₀ is the permittivity of free space. f_{L}, ωₚ, γ_{L} are the strength factor, resonance frequency, and damping rate of the Lorentz oscillator, respectively. The Lorentz model (i.e., the third term) describes the inter-band transmission of electron which contributes to the light absorption in the energy range of 1.0-4.77 eV. The Drude model (i.e., the second term) describes the free-carrier scattering effect in the near infrared (NIR) spectrum.

In certain exemplary embodiments, layer (or thin film) 204 comprises from about 5 wt % to about 20 wt % gallium (Ga), from about 20 wt % to about 80 wt % indium (In), from about 1 wt % to about 10 wt % tin (Sn), and from about 10 wt % to about 30 wt % oxygen (O).

In certain exemplary embodiments, substrate 300 may comprise at least one of silicon, fused silica, glass, a glass ceramic, or a compound semiconductor material. In certain exemplary embodiments, substrate 300 comprises silicon. In certain exemplary embodiments, substrate 300 comprises glass.

Layer (or thin film) 204 may, for example, comprise IGTO that is sputtered away from a target 200 and onto a substrate 300 in an RF sputtering process as described herein.

### EXAMPLES

Embodiments disclosed herein are further illustrated by the following non-limiting examples.

### Example 1

A polycrystalline In₂O₃·SnO₂·Ga₂O₃ target having a diameter of about 12 inches and a thickness of about 0.5 inches was lock loaded in a chamber of a vacuum RF sputtering apparatus. A single crystal n-type silicon wafer having a diameter of about 6 inches and a thickness of about 0.25 inches was positioned in the chamber as substrate for target material deposition. The chamber was heated up to about 200° C. (with temperature measured in-situ by thermocouple) and stabilized for about 2 hours. RF power of about 750 Watts (W) was then applied causing sputtering of In₂O₃·SnO₂·Ga₂O₃ target material onto the substrate at a deposition rate of about 0.8-1.2 nanometers per minute until an IGTO film having a thickness of about 75 nanometers was deposited onto the substrate. During the sputtering, the chamber pressure was fixed at about 2.4 mTorr in an atmosphere comprising argon and oxygen wherein, for different experimental runs, argon was allowed to vary from about 99 mol % to about 93 mol % and the oxygen was allowed to vary from about 1 mol % to about 7 mol %. Following deposition, samples were cooled in-situ to room temperature prior to removal and storage in air.

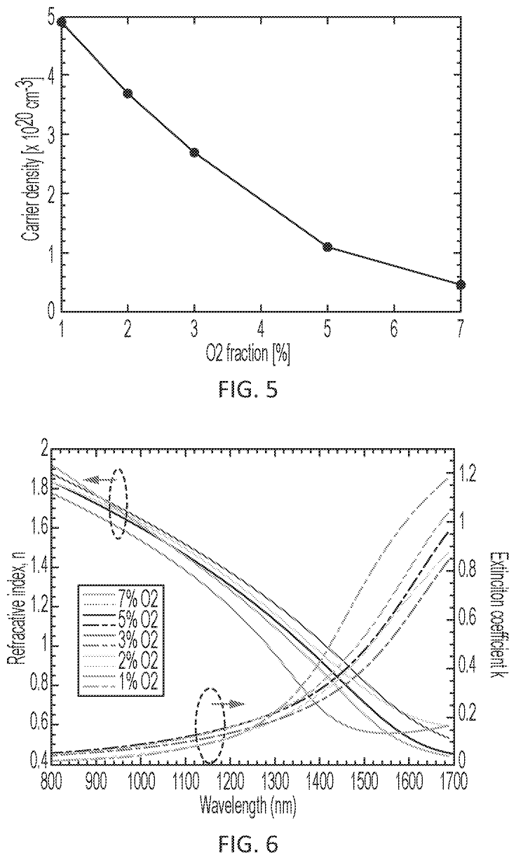

Energy dispersive X-ray (EDX) measurements showed that the composition of as-deposited IGTO films to be about 9.2 wt % gallium (Ga), 68.2 wt % indium (In), 3.5 wt % tin (Sn), and 19.1 wt % oxygen (O) with measured r.m.s. surface roughness of about 0.23 nm. The real and imaginary parts of the complex refractive index Ñ=n−i−k, as a function of wavelength extracted from spectroscopic ellipsometry using the Drude-Lorentz model equation are shown in FIG. 4. The solid lines represent the real part (i.e., refractive index n) showing that n decreases with the O₂ fraction. For example, n decreases from 2.0 to 1.35 at wavelength of 1550 nm when the O₂ fraction changes from about 7% to about 1%. The dashed lines represent the imaginary part (i.e., extinction coefficient k) showing that k increases with the O₂ fraction. For example, k increases from 2.2×10⁴ to 0.23 at wavelength of 1550 nm when the O₂ fraction changes from about 7% to about 1%. Such tailoring of optical properties of the IGTO films is believed to be at least in part due to the change of the free carrier density by controlling the density of oxygen vacancies. FIG. 5 shows the extracted carrier density in the as-deposited IGTO films for different O₂ fraction. By changing the O₂ fraction from 7% to 1%, the carrier density increases by more than one order of magnitude from 0.46×10²⁰ to 4.9×10²⁰.

### Example 2

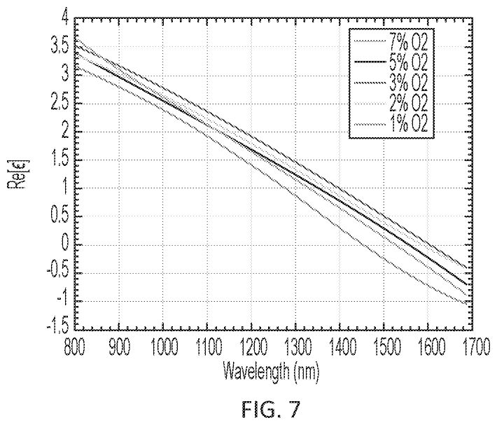

A series of samples comprising IGTO films prepared under the conditions of Example 1 were thermally annealed in a chamber of a thermal annealing apparatus for about 45 minutes at about 450° C. in an atmosphere comprising about 97 mol % nitrogen and about 3 mol % hydrogen. The IGTO films of the thermally annealed samples had a measured r.m.s. surface roughness of about 1.0 nm. The real and imaginary parts of the complex refractive index Ñ=n−i−k, as a function of wavelength extracted from spectroscopic ellipsometry using the Drude-Lorentz model equation are shown in FIG. 6. As compared to FIG. 4, FIG. 6 shows that annealing can significantly change the optical properties such that refractive index (n) can be further reduced below 1.0 and extinction coefficient (k) becomes even larger at wavelength of 1550 nm for all O₂ fractions. Such significant change of the optical properties can result in the annealed IGTO films becoming epsilon-near-zero (ENZ) in or around the near infrared spectrum (NIR). FIG. 7 shows that the ENZ wavelength of the annealed IGTO films has been tailored around telecommunication band, ranging from 1455 nm to 1605 nm.

Accordingly, embodiments disclosed herein can include IGTO films having a refractive index (n) at 1550 nanometers of less than about 1.5, such as less than about 1.2, and further such as less than about 1.0, such as from about 0.5 to about 1.5, and further such as from about 0.5 to about 1.2, and yet further such as from about 0.5 to about 1.0. Embodiments disclosed herein can also include IGTO films having an extinction coefficient (k) at 1550 nanometers of greater than about 0.3, such as greater than about 0.4, and further such as greater than about 0.5, such as from about 0.3 to about 1.2, and further such as from about 0.4 to about 1.1, and yet further such as from about 0.5 to about 1.0. In addition, embodiments disclosed herein can include IGTO films having an epsilon (F) at 1550 nanometers of from about 0.5 to about −0.5, such as from about 0.4 to about −0.4, and further such as from about 0.3 to about −0.3, and yet further such as from about 0.2 to about −0.2, and still yet further such as from about 0.1 to about −0.1, including about 0.

Moreover, embodiments disclosed herein can enable composite materials with IGTO films, which can be used in a variety of applications, such as displays, sensors, modulators, optical interconnects, optical switches, tunable absorbers, information processing devices, nanophotonic devices, and/or metamaterials to name a few. In such applications, IGTO films made in accordance with embodiments disclosed herein can impart advantages such as high optical transparency, high electron mobility, high on/off current ratio, and low-temperature operation. Moreover, embodiments disclosed herein can enable the manufacture of IGTO films with tunable properties. For example, significant refractive index change can be achieved by tuning the free carrier concentration either through oxygen vacancy doping or electrical gating. In addition, when the free carrier concentration reaches a threshold, the so-called epsilon-near-zero (ENZ) effect occurs in the near infrared spectrum (e.g. telecommunication wavelength band) in which the real part of the permittivity reaches zero and thus the light-matter interaction can be drastically enhanced. Moreover, as the free carriers accumulate, the optical absorption of the IGTO dramatically increases (such as two orders of magnitude larger than that of silicon), which is favorable for EA modulators. Therefore, embodiments disclosed herein can potentially achieve ultra-high modulation and energy efficiency as well as an ultra-small footprint.

Accordingly, embodiments disclosed herein include electronic devices comprising composites of a target material and a substrate as disclosed herein, including composites of a target material and a substrate made by RF sputtering techniques as disclosed herein.

It will be apparent to those skilled in the art that various modifications and variations can be made to embodiments of the present disclosure without departing from the spirit and scope of the disclosure. Thus, it is intended that the present disclosure cover such modifications and variations provided they come within the scope of the appended claims and their equivalents.

What is claimed is:

1. A method of manufacturing a composite of a target material and a substrate comprising:
positioning the substrate and a target in a chamber and applying radio frequency (RF) power to the chamber to sputter ions of target material from the target onto the substrate;
wherein the target material comprises indium oxide (In₂O₃), tin oxide (SnO₂), and gallium oxide (Ga₂O₃).

2. The method of claim 1, wherein the method further comprises thermally annealing the composite.

3. The method of claim 2, wherein the thermal annealing comprises maintaining the composite at a temperature of at least about 300° C. for a time of at least about 10 minutes.

4. The method of claim 1, wherein a gas comprising at least one of helium, nitrogen, neon, or argon is flowed into the chamber during the sputtering of ions of target material from the target onto the substrate.

5. The method of claim 4, wherein the gas comprises a combination of argon and oxygen, wherein the fraction of argon ranges from about 90% mol % to about 99.9% mol % and the fraction of oxygen ranges from about 0.1 mol % to about 10 mol %.

6. The method of claim 1, wherein the method comprises evacuating gaseous fluid out of chamber such that the absolute pressure inside chamber is less than about 25 mTorr during the sputtering of ions of target material from the target onto the substrate.

7. The method of claim 1, wherein the substrate comprises at least one of silicon, fused silica, glass, a glass ceramic, or a compound semiconductor material.

8. The method of claim 1, wherein the target comprises polycrystalline In₂O₃·SnO₂·Ga₂O₃.

9. The method of claim 1, wherein the target material comprises from about 5 wt % to about 20 wt % gallium (Ga), from about 20 wt % to about 80 wt % indium (In), from about 1 wt % to about 10 wt % tin (Sn), and from about 10 wt % to about 30 wt % oxygen (O).

10. The method of claim 1, wherein, during the sputtering of ions of target material from the target onto the substrate, a deposition rate of target material onto the substrate ranges from about 0.1 nanometers to about 10 nanometers per minute.

11. A composite comprising a substrate and a target material, wherein the target material comprises indium oxide (In₂O₃), tin oxide (SnO₂), and gallium oxide (Ga₂O₃).

12. The composite of claim 11, wherein the substrate comprises at least one of silicon, fused silica, glass, a glass ceramic, or a compound semiconductor material.

13. The composite of claim 12, wherein the substrate comprises silicon.

14. The composite of claim 12, wherein the substrate comprises glass.

15. The composite of claim 11, wherein the target material comprises from about 5 wt % to about 20 wt % gallium (Ga), from about 20 wt % to about 80 wt % indium (In), from about 1 wt % to about 10 wt % tin (Sn), and from about 10 wt % to about 30 wt % oxygen (O).

16. The composite of claim 11, wherein a thickness of the substrate ranges from about 100 microns (μm) to about 10 millimeters (mm) and a thickness of the target material ranges from about 1 nanometer (nm) to about 10 microns (μm).

17. The composite of claim 11, wherein the target material has a refractive index (n) at 1550 nanometers of less than about 1.5.

18. The composite of claim 11, wherein the target material has an extinction coefficient (k) at 1550 nanometers of greater than about 0.3.

19. The composite of claim 11, wherein the target material has an epsilon (F) at 1550 nanometers of from about 0.5 to about −0.5.

20. An electronic device comprising the composite of claim 11.
